(19) United States
(12) Patent Application Publication
(10) Pub. No.: US 2026/0171516 A1
(43) Pub. Date: Jun. 18, 2026

(54) BATTERY MANAGEMENT SYSTEM HAVING CONTINUOUS BATTERY CELL MONITORING FUNCTION AND OPERATING METHOD THEREFOR

(71) Applicants: HYUNDAI MOTOR COMPANY, Seoul (KR); KIA CORPORATION, Seoul (KR)

(72) Inventors: SungWook An, Hwaseong-si (KR); Jonghu Yoon, Hwaseong-si (KR); Hwanseok Kim, Hwaseong-si (KR)

(73) Assignees: HYUNDAI MOTOR COMPANY, Seoul (KR); KIA CORPORATION, Seoul (KR)

(21) Appl. No.: 19/243,149

(22) Filed: Jun. 19, 2025

(30) Foreign Application Priority Data
Dec. 17, 2024 (KR) 10-2024-0188518

(51) Int. Cl. H01M 10/42; B60L 3/00; G01R 31/374; G01R 31/3835; G01R 31/396

(52) U.S. Cl. CPC H01M 10/425; B60L 3/0046; G01R 31/374; G01R 31/3835; G01R 31/396; H01M 2010/4271; H01M 2220/20

(57) ABSTRACT

A battery management system with a continuous battery cell monitoring function includes a cell monitoring unit (CMU) configured to continuously monitor a status of a plurality of battery cells included in a battery module. The CMU is further configured to, upon detecting an abnormal state of at least one battery cell, notify a battery management unit (BMU) of the abnormal state of the at least one battery cell. The system further includes the BMU configured to manage the at least one CMU. The BMU is further configured to, upon receiving notification of the abnormal state of the at least one battery cell from the CMU, transition from a sleep mode to an active mode and respond to the abnormal state of the at least one battery cell.

### CROSS-REFERENCE TO RELATED APPLICATION

This present application claims the benefit of and priority to Korean Patent Application No. 10-2024-0188518, filed on Dec. 17, 2024, in the Korean Intellectual Property Office, the entire disclosure of which are incorporated herein by reference.

### TECHNICAL FIELD

The present disclosure relates to a battery management system and an operating method therefor. More particularly, the present disclosure relates to a battery management system having a function for continuously monitoring battery cells of a high-voltage battery even while an electric vehicle is parked, and an operating method therefor.

### BACKGROUND

Batteries used in environmentally friendly vehicles, such as electric vehicles (EVs), hybrid electric vehicles (HEVs), and plug-in hybrid electric vehicles (PHEVs), are high-voltage batteries that generate high voltage by connecting numerous battery cells of the same specifications in series/parallel.

A battery management system (BMS) is a device that controls and manages charging and discharging of such high-voltage batteries including numerous battery cells. The BMS includes at least one cell monitoring unit (CMU) that monitors the battery cells and a battery management unit (BMU) that manages the at least one CMU.

In existing technology, the BMU and the CMU of a battery management system operate normally in an active mode while the vehicle is driving. However, when the ignition (IG) is turned off, the BMU and the CMU transition to a sleep mode after a predetermined time (e.g., 2 hours) while the vehicle is parked. Then, the BMU and the CMU wake up periodically (e.g., at 10-minute intervals) for a very short time period (e.g., 10 seconds) to monitor the battery cells. After an additional predetermined time (e.g., 58 hours) has elapsed since the ignition was turned off, the BMU and the CMU transition to a total sleep mode and do not perform battery cell monitoring.

However, recently, fires caused by batteries in parked electric vehicles have occurred frequently. In existing technology, because the BMU and the CMU transition to the sleep mode while the vehicle is parked and wake up only intermittently at relatively long intervals (e.g., every 10 minutes) for a very short time period (e.g., 10 seconds) to perform battery cell monitoring, abnormalities, such as battery cell overvoltage, undervoltage, over-temperature, or under-temperature, may occur during a time when the BMU and the CMU are not awake. In such a case, by the time the BMU and the CMU wake up and respond, a fire may have already progressed rapidly and thus may result in significant damage to property and people.

Moreover, if the BMU and the CMU are operated normally in the active mode while the vehicle is parked, the power consumption of an auxiliary battery of the vehicle (e.g., a 12V lead-acid battery) that operates the BMU while the vehicle is parked increases and thus causes the auxiliary battery to discharge easily. The subject matter described in this background section is intended to promote an understanding of the background of the disclosure and thus may include subject matter that is not already known to those of ordinary skill in the art. The statements in this section merely provide background information related to the present disclosure and may not constitute prior art.

### SUMMARY

The present disclosure provides a battery management system and an operating method therefor with a function of continuously monitoring battery cells of a high-voltage battery while an electric vehicle is parked, without significantly consuming power of an auxiliary battery of the vehicle.

The present disclosure further provides a battery management system and an operating method therefor with a continuous battery cell monitoring function in which a cell monitoring unit (CMU) continuously monitors the battery cells while the electric vehicle is parked, and upon detecting an abnormal state of a battery cell, notifies a battery management unit (BMU) to respond to the abnormal state.

Aspects of the present disclosure are not limited to those mentioned above. Other aspects and advantages not mentioned above should be understood from the present disclosure and become more apparent from the embodiments. Moreover, aspects of the present disclosure may be realized by the means and combinations thereof indicated in claims.

According to one aspect of the present disclosure, a battery management system with a continuous battery cell monitoring function includes a cell monitoring unit (CMU) configured to continuously monitor a status of a plurality of battery cells included in a battery module. The CMU is further configured to, upon detecting an abnormal state of at least one battery cell, notify a battery management unit (BMU) of the abnormal state of the at least one battery cell. The system further includes the BMU configured to manage the at least one CMU. The BMU is further configured to, upon receiving notification of the abnormal state of the at least one battery cell from the CMU, transition from a sleep mode to an active mode and respond to the abnormal state of the at least one battery cell.

In an embodiment, the BMU is further configured to transition from the active mode to the sleep mode when the ignition is turned off.

In an embodiment, the BMU is further configured to operate in the sleep mode by using standby power of an external battery after the ignition is turned off.

In an embodiment, the CMU is further configured to operate in the active mode during a preset continuous monitoring time period after the ignition is turned off.

According to another aspect of the present disclosure, a battery management system with a continuous battery cell monitoring function includes a cell monitoring unit (CMU) including a battery cell monitoring unit configured to continuously monitor a status of a plurality of battery cells included in a battery module and generate battery cell status information. The CMU further includes a battery management unit (BMU) interface unit configured to communicate with the BMU and transmit the battery cell status information to a BMU. The system further includes the BMU including a CMU interface unit configured to communicate with the CMU and receive the battery cell status information. The BMU further includes a power supply unit configured to supply standby power of an external battery to the CMU interface unit. The BMU further includes a control unit configured to manage the CMU based on the battery cell status information received through the CMU interface unit. The battery cell monitoring unit of the CMU is further configured to, upon detecting an abnormal state of at least one battery cell, notify the BMU of the abnormal state of the at least one battery cell through the BMU interface unit of the CMU. The control unit of the BMU is further configured to, upon receiving notification of the abnormal state of the at least one battery cell from the CMU through the CMU interface unit of the BMU, transition from a sleep mode to an active mode and respond to the abnormal state of the at least one battery cell.

In an embodiment, the CMU interface unit of the BMU is further configured to wake up the control unit of the BMU upon receiving notification of the abnormal state of the at least one battery cell from the BMU interface unit of the CMU.

In an embodiment, upon being woken up by the CMU interface unit of the BMU, the control unit of the BMU is further configured to: request battery cell status information from the CMU through the CMU interface unit of the BMU, and determine whether the abnormal state of the at least one battery cell exists based on the battery cell status information received from the CMU.

In an embodiment, the CMU interface unit of the BMU is further configured to continuously operate by using the standby power of the external battery supplied from the power supply unit of the BMU after the ignition is turned off.

According to another aspect of the present disclosure, a method for operating a battery management system with a continuous battery cell monitoring function includes: continuously monitoring, by a cell monitoring unit (CMU), a status of a plurality of battery cells included in a battery module. The method further includes detecting, by the CMU, an abnormal state of at least one battery cell. The method further includes notifying, by the CMU, a battery management unit (BMU) of the abnormal state of the at least one battery cell. The method further includes transitioning, by the BMU, from a sleep mode to an active mode. The method further includes responding, by the BMU, to the abnormal state of the at least one battery cell upon receiving notification of the abnormal state of the at least one battery cell from the CMU.

In an embodiment, continuously monitoring includes operating the CMU in the active mode during a preset continuous monitoring time period after an ignition is turned off.

In an embodiment, responding to the abnormal state includes waking up, by a CMU interface unit of the BMU, a control unit of the BMU. Responding to the abnormal state further includes requesting, by the control unit of the BMU, battery cell status information from the CMU through the CMU interface unit of the BMU. Responding to the abnormal state further includes determining, by the control unit of the BMU, whether the abnormal state of the at least one battery cell exists based on the battery cell status information received from the CMU. Responding to the abnormal state further includes responding, by the control unit of the BMU, upon an abnormal state of the battery cell being determined, to the abnormal state of the at least one battery cell.

According to the present disclosure, when the ignition is turned off, the BMU transitions from the active mode to the sleep mode, and the CMU performs continuous monitoring. This enables continuous monitoring of battery cells in a high-voltage battery while an electric vehicle is parked, without significantly consuming the power of an auxiliary battery of the vehicle.

Moreover, according to the present disclosure, the CMU continuously monitors the battery cells while the electric vehicle is parked and, upon detecting an abnormal state of a battery cell, notifies the BMU so that the abnormal state of the battery cell can be immediately responded to. This enables fires caused by the battery to be addressed before progressing significantly, thereby greatly reducing damage to property and people.

### BRIEF DESCRIPTION OF THE DRAWINGS

The foregoing and other aspects, features, and advantages of the present disclosure, as well as the following detailed description of the embodiments, should be better understood when read in conjunction with the accompanying drawings. For the purpose of illustrating the present disclosure, the drawings show the embodiments. However, it should be understood that the present disclosure is not intended to be limited to the details shown in the drawings. Instead, various modifications and structural changes may be made therein without departing from the spirit of the present disclosure and within the scope and range of equivalents of the claims. Like reference numbers and designations in the various drawings indicate like elements.

FIG. 1 illustrates an operating method for a battery management unit (BMU) and a cell monitoring unit (CMU) according to existing technology in a normal situation.

FIG. 2 illustrates an operating method for the BMU and the CMU according to existing technology in a situation in which an abnormality has occurred.

FIG. 3 illustrates an operating method for a BMU and a CMU according to one embodiment of the present disclosure in a normal situation.

FIG. 4 illustrates an operating method for the BMU and the CMU according to one embodiment of the present disclosure in a situation in which an abnormality has occurred.

FIG. 5 is a block diagram of a battery management system with a continuous battery cell monitoring function according to one embodiment of the present disclosure.

FIG. 6 is a flowchart illustrating a method for operating a battery management system with a continuous battery cell monitoring function according to one embodiment of the present disclosure.

### DETAILED DESCRIPTION

The embodiments of the present disclosure are described in greater detail with reference to the accompanying drawings. Throughout the accompanying drawings, the same reference numerals are used to designate the same, similar, or equivalent components. Redundant descriptions of the embodiments have omitted herein. The terms, such as “module” and “unit,” refer to components are used interchangeably in consideration of convenience of explanation. Thus, the terms per se should not be considered as having different meanings or functions. In relation to describing the present disclosure, when the detailed description of the relevant known technology is determined to unnecessarily obscure the gist of the present disclosure, the detailed description has been omitted. Furthermore, it should be understood that the appended drawings are intended only to help understand embodiments disclosed in the present document and do not limit the technical principles and scope of the present disclosure. Instead, it should be understood that the appended drawings include all of the modifications, equivalents, or substitutes described by the technical principles and belonging to the technical scope of the present disclosure.

Although the terms, such as first, second, third, and the like, may be used herein to describe various elements, components, regions, layers, and/or sections, these elements, components, regions, layers, and/or sections should not be limited by these terms. These terms are only used to distinguish one element from another.

When an element or a layer is referred to as being “on,” “engaged to,” “connected to,” or “coupled to” another element or another layer, the element or the layer may be directly on, engaged, connected, or coupled to another element or another layer, or intervening elements or layers may be present between the elements or the layers. In contrast, when an element is referred to as being “directly on,” “directly engaged to,” “directly connected to,” or “directly coupled to” another element or layer, there may be no intervening elements or layers present between the elements or the layers. When a controller, apparatus, module, component, device, element, or the like of the present disclosure is described as having a purpose or performing an operation, function, or the like, the controller, apparatus, module, component, device, element, or the like should be considered herein as being “configured to” meet that purpose or to perform that operation or function. Each controller, apparatus, module, component, device, element, and the like may separately embody or be included with a processor and a memory, such as a non-transitory computer readable media, as part of the apparatus.

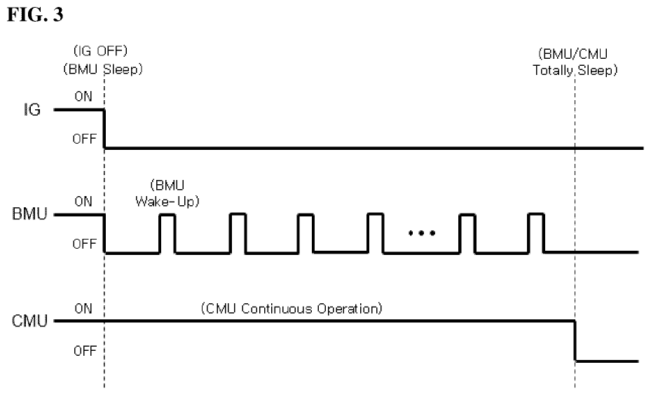

Hereinafter, a battery management system with a continuous battery cell monitoring function according to the present disclosure, and an operating method therefor, are described in detail with reference to FIGS. 3-6.

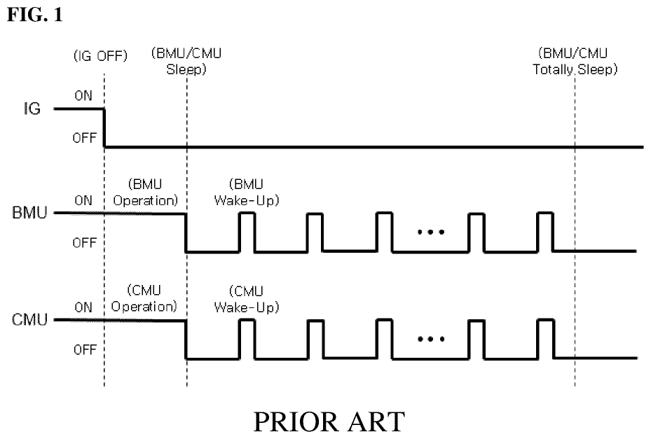

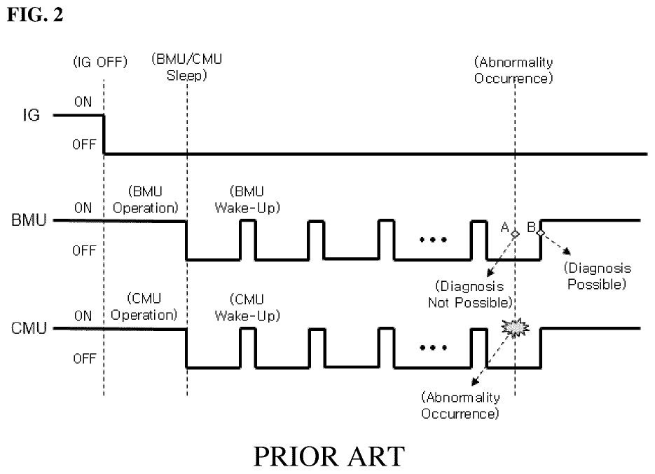

Before describing the present disclosure, an operating method for a battery management unit (BMU) and a cell monitoring unit (CMU) according to existing technology is described with reference to FIGS. 1 and 2.

FIG. 1 illustrates an operating method for a BMU and a CMU according to existing technology in a normal situation, and FIG. 2 illustrates an operating method for the BMU and the CMU according to existing technology in a situation in which an abnormality has occurred.

Referring to FIG. 1, in the existing technology, after an ignition (IG) is turned off, the BMU and the CMU operate normally in an active mode for a first predetermined time period (e.g., 2 hours). When a first predetermined time period has elapsed after the ignition is turned off, the BMU and the CMU transition from the active mode to a sleep mode. During a second predetermined time period (e.g., 58 hours), the BMU and the CMU periodically wake up (e.g., at 10-minute intervals) for a very short time period (e.g., 10 seconds) to perform battery cell monitoring. Once the second predetermined time period elapses, the BMU and the CMU enter a total sleep mode, during which battery cell monitoring is not performed.

Referring to FIG. 2, in the existing technology, when the first predetermined time period has elapsed after the ignition is turned off and the BMU and the CMU transition from the active mode to the sleep mode, the BMU and the CMU intermittently wake up for a very short time period at relatively long intervals during a second predetermined time period to perform battery cell monitoring. Here, if a battery cell abnormality, such as overvoltage, undervoltage, over-temperature, or under-temperature, occurs while the BMU and the CMU are in the sleep mode (see time A in FIG. 2), battery cell diagnosis cannot be performed until the BMU and the CMU wake up again (see time B in FIG. 2). As a result, fire progresses rapidly until the BMU and the CMU wake up and respond. This causes significant damage to property and people.

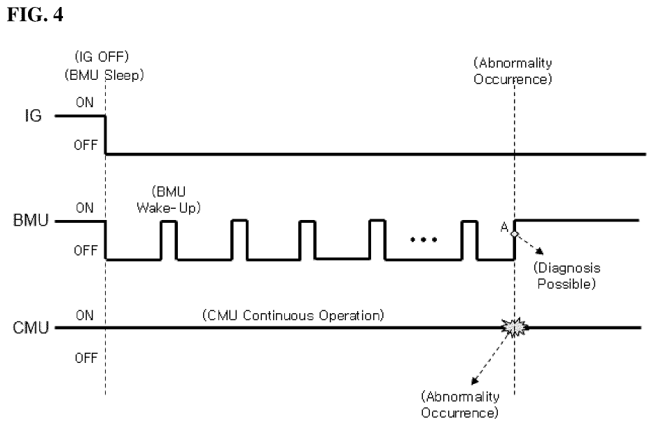

Hereinafter, an operating method for a BMU and a CMU according to one embodiment of the present disclosure in a normal situation is described with reference to FIGS. 3 and 4.

FIG. 3 illustrates an operating method for a BMU and a CMU according to one embodiment of the present disclosure in a normal situation, and FIG. 4 illustrates an operating method for the BMU and the CMU according to one embodiment of the present disclosure in a situation in which an abnormality has occurred.

Referring to FIG. 3, in one embodiment of the present disclosure, after an ignition (IG) is turned off, the BMU transitions from the active mode to the sleep mode and periodically wakes up (e.g., at 10-minute intervals) for a very short time period (e.g., 10 seconds) during a third predetermined time period (e.g., 60 hours) to intermittently manage the CMU. By contrast, after the ignition is turned off, the CMU maintains the active mode during the third predetermined time period (continuous monitoring time period) to perform continuous monitoring of the battery cells. Once the third predetermined time period elapses, both the BMU and the CMU transition to the total sleep mode and do not perform battery cell monitoring.

Referring to FIG. 4, in one embodiment of the present disclosure, the CMU maintains the active mode during the continuous monitoring time period after the ignition is turned off and performs continuous monitoring of the battery cells. Here, if a battery cell abnormality, such as overvoltage, undervoltage, over-temperature, or under-temperature, occurs at any time (see time A in FIG. 4), the CMU in the active mode immediately detects the abnormal state of the battery cell. Then, the CMU notifies the BMU of the abnormal state of the battery cell, and the BMU transitions from the sleep mode to the active mode to respond to the abnormal state of the battery cell.

Hereinafter, a battery management system with a continuous battery cell monitoring function and an operating method therefor, for implementing the operating method for the BMU and the CMU according to the embodiment of the present disclosure as described above, are explained according to one embodiment of the present disclosure.

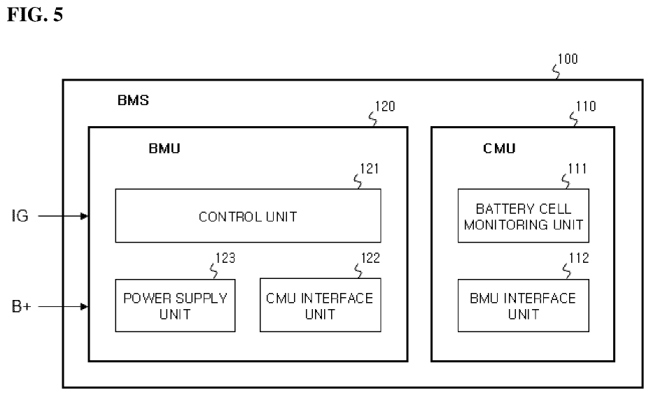

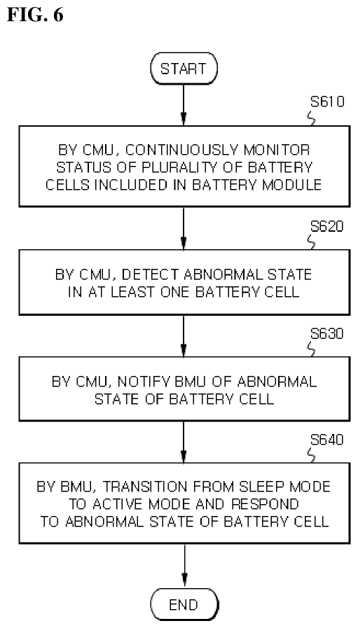

FIG. 5 is a block diagram of a battery management system with a continuous battery cell monitoring function according to one embodiment of the present disclosure. FIG. 6 is a flowchart illustrating a method for operating a battery management system with a continuous battery cell monitoring function according to one embodiment of the present disclosure.

Referring to FIG. 5, a battery management system (BMS) 100 with a continuous battery cell monitoring function according to one embodiment of the present disclosure comprises at least one cell monitoring unit (CMU) 110 configured to monitor a status of at least one battery module and comprises a battery management unit BMU (120) configured to manage the at least one CMU.

The CMU 110 constantly monitors the status (e.g., voltage, current, temperature) of a plurality of battery cells included in the battery module, generates battery cell status information, and transmits the battery cell status information to the BMU 120.

To this end, the CMU 110 according to one embodiment of the present invention comprises a battery cell monitoring unit 111 and a BMU interface unit 112, etc.

The battery cell monitoring unit 111 performs battery cell continuous monitoring by maintaining an active mode during a preset continuous monitoring time period (third predetermined time period) even after the ignition is turned off and the vehicle is parked (S610 in FIG. 6) and transmits battery cell status information to the BMU 120 through the BMU interface unit 112. When the battery cell monitoring unit 111 detects an abnormal state in at least one battery cell during the continuous monitoring (see S620 in FIG. 6), the battery cell monitoring unit 111 notifies the BMU 120 of the abnormal state of the battery cell through the BMU interface unit 112 (see S630 in FIG. 6). The battery cell monitoring unit 111 may be implemented as a battery monitoring integrated circuit (BMIC) or the like.

The BMU interface unit 112 communicates with the BMU 120 (specifically, a CMU interface unit of the BMU) to transmit the battery cell status information generated by the battery cell monitoring unit 111 to the BMU 120, receives control information from the BMU 120, and transmits the information to the battery cell monitoring unit 111. When the BMU interface unit 112 receives notification of an abnormal state of a battery cell from the battery cell monitoring unit 111, the BMU interface unit 112 transmits the notification to the BMU 120. The BMU interface unit 112 may be implemented as an interface integrated circuit (IC) or the like.

The BMU 120 receives the battery cell status information from the CMU 110 and determines a status of the battery cells and based thereon, performs operations, such as charging, discharging, and balancing. If the BMU 120 receives notification of an abnormal state of a battery cell from the CMU 110, the BMU 120 performs action (control) to address the abnormal state.

To this end, the BMU 120 according to one embodiment of the present disclosure comprises a control unit 121, a CMU interface unit 122, and a power supply unit 123, etc.

The control unit 121 manages and controls the CMU 110 based on the battery cell status information received from the CMU 110. If the control unit 121 receives notification of an abnormal state of the battery cell from the CMU 110 while in the sleep mode after the ignition is turned off, the control unit 121 transitions to the active mode, determines whether a battery cell abnormality exists, and performs action (control) to respond to the abnormal state of the battery cell (see S640 in FIG. 6). The control unit 121 may be implemented as a microcontroller unit (MCU), a central processing unit (CPU), or the like.

The CMU interface unit 122 communicates with the CMU 110 (specifically, the BMU interface unit of the CMU), transmits the battery cell status information transmitted from the CMU 110 to the control unit 121, and receives control information from the control unit 121 and transmits the information to the CMU 110. When the CMU interface unit 122 receives notification of an abnormal state of a battery cell from the CMU 110, the CMU interface unit 122 wakes up the control unit 121 and notifies the control unit 121 of the abnormal state of the battery cell. The CMU interface unit 122 may be implemented as an interface integrated circuit (IC) or the like.

The power supply unit 123 supplies standby power (e.g., B+ power) from a vehicle's auxiliary battery (from the BMU's perspective, an external battery) to the control unit 121 and the CMU interface unit 122. Even when the ignition is off and the control unit 121 is in the sleep mode (a non-operating state), the power supply unit 123 continuously supplies power to the CMU interface unit 122 and thus maintains the CMU interface unit 122 in an on state so that communication between the CMU interface unit 122 and the BMU interface unit 112 is always possible. The power supply unit 123 may be implemented as a power management integrated circuit (PMIC) or the like.

Hereinafter, an operating method for a BMU and a CMU according to one embodiment of the present disclosure is comprehensively described with reference to FIGS. 3-6.

After the ignition (IG) is turned off, the control unit 121 of the BMU 120 sets the power supply unit 123, which is connected to the standby power (e.g., B+ power) of an external battery (e.g., 12 V lead-acid battery), to continuously operate, so that the standby power of the external battery can be continuously supplied to the CMU interface unit 122. In addition, the control unit 121 of the BMU 120 sets the CMU interface unit 122 to operate continuously and thus enables constant communication with the BMU interface unit 112 of the CMU 110.

The control unit 121 of the BMU 120 transitions from the active mode to the sleep mode to minimize power consumption.

The power supply unit 123 uses a real-time clock (RTC) or the like to periodically (e.g., every 10 minutes) wake up the control unit 121 for a very short time period (e.g., 10 seconds) during a preset continuous monitoring time period (e.g., 60 hours). Then, while being woken up, the control unit 121 communicates with the CMU 110 through the CMU interface unit 122 to perform battery cell monitoring.

The CMU 110 maintains the active mode during the continuous monitoring time period even after the ignition (IG) is turned off and continuously monitors the status of the battery cells (see S610 in FIG. 6).

In a normal situation, once the continuous monitoring time period elapses, the CMU 110 and the BMU 120 transition to a total sleep mode and do not perform battery cell monitoring.

However, if a battery cell abnormality, such as overvoltage, undervoltage, over-temperature, or under-temperature, occurs (e.g., overvoltage, undervoltage, over-temperature, under-temperature is detected a predetermined number of times or more) at any time during the continuous monitoring of the CMU 110 (see time A in FIG. 4), the battery cell monitoring unit 111 of the CMU 110 in the active mode immediately detects the abnormal state of the battery cell (see S620 in FIG. 6) and notifies the BMU 120 of the abnormal state of the battery cell through the BMU interface unit 112 (see S630 in FIG. 6).

When the CMU interface unit 122 of the BMU 120 receives a notification of the abnormal state of the battery cell from the BMU interface unit 112 of the CMU 110, the CMU interface unit 122 of the BMU 120 wakes up the control unit 121 of the BMU 120.

Then, the control unit 121 of the BMU 120 transitions from the sleep mode to the active mode and identifies the cause of the wake-up. If the control unit 121 of the BMU 120 determines that the wake-up is caused by the CMU interface unit 122, the control unit 121 of the BMU 120 requests battery cell status information from the CMU 110 through the CMU interface unit 122 of the BMU 120 and determines whether an abnormal state of a battery cell exists based on the battery cell status information received from the CMU 110.

If an abnormal state of the battery cell is determined, the control unit 121 of the BMU 120 and the CMU interface unit 122 of the BMU 120 each store the battery cell status information so as to store the battery cell status information in duplicate, and the control unit 121 of the BMU 120 performs action (control) to respond to the abnormal state of the battery cell (see S640 in FIG. 6).

As described above, according to the present disclosure, when the ignition is turned off, the BMU transitions from the active mode to the sleep mode, and the CMU performs continuous monitoring. This enables continuous monitoring of battery cells in a high-voltage battery while an electric vehicle is parked, without significantly consuming the power of an auxiliary battery of the vehicle.

For example, in existing technology, after the ignition is turned off, the BMU and the CMU operate normally in the active mode for 2 hours and then wake up every 10 minutes for 10 seconds over the next 58 hours to perform battery cell monitoring, consuming approximately 13 mA of power. Further, if the BMU and the CMU operate continuously in the active mode for 60 hours after the ignition is turned off, approximately 200 mA of power is consumed.

However, according to the present disclosure, after the ignition is turned off, the BMU transitions from the active mode to the sleep mode, and only the CMU interface unit continuously operates using the standby power of the external battery (e.g., B+ power). As a result, only about 8.1 mA of power is consumed over 60 hours after the ignition is turned off. Thus, this prevents the external battery from discharging while also enabling continuous monitoring of the battery cells.

As used in the present disclosure (especially in the appended claims), the terms “a/an” and “the” include both singular and plural referents, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. In other words, the present disclosure is not necessarily limited to the order in which the steps are recited. All examples described in the present disclosure or the terms indicative thereof (“for example”, “such as”) are merely to describe the present disclosure in greater detail. Therefore, it should be understood that the scope of the present disclosure is not limited to the example embodiments described above or by the use of such terms unless limited by the appended claims. Also, it should be apparent to those having ordinary skill in the art that various modifications, combinations, and alternations may be made based on design conditions and factors within the scope of the appended claims or equivalents thereof.

The present disclosure is thus not limited to the embodiments described above but is intended to include the following appended claims and all modifications, equivalents, and alternatives falling within the spirit and scope of the following claims.

What is claimed is:

1. A battery management system comprising:
a cell monitoring unit (CMU) configured to:
continuously monitor a status of a plurality of battery cells included in a battery module; and
upon detecting an abnormal state of at least one battery cell of the plurality of battery cells, notify a battery management unit (BMU) of the abnormal state of the at least one battery cell; and
the BMU configured to:
manage the CMU; and
upon receiving notification of the abnormal state of the at least one battery cell from the CMU, transition from a sleep mode to an active mode and respond to the abnormal state of the at least one battery cell.

2. The battery management system according to claim 1, wherein the BMU is further configured to transition from the active mode to the sleep mode when an ignition is turned off.

3. The battery management system according to claim 2, wherein the BMU is further configured to operate in the sleep mode by using standby power of an external battery after the ignition is turned off.

4. The battery management system according to claim 1, wherein the CMU is further configured to operate in the active mode during a preset continuous monitoring time period after an ignition is turned off.

5. A battery management system for a vehicle, the battery management system comprising:
a cell monitoring unit (CMU) comprising:
a battery cell monitoring unit configured to continuously monitor a status of a plurality of battery cells included in a battery module and generate battery cell status information; and
a battery management unit (BMU) interface unit configured to communicate with a BMU and transmit the battery cell status information to the BMU; and
the BMU comprising:
a CMU interface unit configured to communicate with the CMU and receive the battery cell status information;
a power supply unit configured to supply standby power of an external battery to the CMU interface unit; and
a control unit configured to manage the CMU based on the battery cell status information received through the CMU interface unit,
wherein the battery cell monitoring unit of the CMU is further configured to notify, upon detecting an abnormal state of at least one battery cell among the plurality of battery cells, the BMU of the abnormal state of the at least one battery cell through the BMU interface unit of the CMU, and
wherein the control unit of the BMU is further configured to, upon receiving notification of the abnormal state of the at least one battery cell from the CMU through the CMU interface unit of the BMU, transition from a sleep mode to an active mode and respond to the abnormal state of the at least one battery cell.

6. The battery management system according to claim 5, wherein upon receiving the notification of the abnormal state of the at least one battery cell from the BMU interface unit of the CMU, the CMU interface unit of the BMU is further configured to wake up the control unit of the BMU.

7. The battery management system according to claim 6, wherein upon being woken up by the CMU interface unit of the BMU, the control unit of the BMU is further configured to:
request the battery cell status information from the CMU through the CMU interface unit of the BMU; and
determine whether the abnormal state of the at least one battery cell exists based on the battery cell status information received from the CMU.

8. The battery management system according to claim 5, wherein the CMU interface unit of the BMU is further configured to continuously operate by using the standby power of the external battery supplied by the power supply unit of the BMU after an ignition is turned off.

9. The battery management system according to claim 5, wherein the battery cell monitoring unit of the CMU is further configured to operate in the active mode during a preset continuous monitoring time period after an ignition is turned off.

10. The battery management system according to claim 5, wherein the control unit of the BMU is further configured to set the CMU interface unit to continuously operate during a preset continuous monitoring time period when an ignition is turned off.

11. The battery management system according to claim 5, wherein the control unit of the BMU is further configured to transition from the active mode to the sleep mode when an ignition is turned off.

12. The battery management system according to claim 5, wherein the control unit of the BMU and the CMU interface unit of the BMU are further configured to store the battery cell status information in duplicate.

13. A method for operating a battery management system, the method comprising:
continuously monitoring, by a cell monitoring unit (CMU), a status of a plurality of battery cells included in a battery module;
detecting, by the CMU, an abnormal state of at least one battery cell among the plurality of battery cells;
notifying, by the CMU, a battery management unit (BMU) of the abnormal state of the at least one battery cell;
transitioning, by the BMU, from a sleep mode to an active mode; and
responding, by the BMU, to the abnormal state of the at least one battery cell upon receiving notification of the abnormal state of the at least one battery cell from the CMU.

14. The method according to claim 13, wherein continuously monitoring comprises:
operating the CMU in the active mode during a preset continuous monitoring time period after an ignition is turned off.

15. The method according to claim 13, wherein responding to the abnormal state comprises:
waking up, by a CMU interface unit of the BMU, a control unit of the BMU;
requesting, by the control unit of the BMU, battery cell status information from the CMU through the CMU interface unit of the BMU;
determining, by the control unit of the BMU, whether the abnormal state of the at least one battery cell exists based on the battery cell status information received from the CMU; and
responding, by the control unit of the BMU, based on the determined abnormal state of the at least one battery cell, to the abnormal state of the at least one battery cell.

16. The method according to claim 13, further comprising, prior to the detecting an abnormal state,
transitioning, by the BMU, from the active mode to the sleep mode after an ignition is turned off.
